(19) United States
(12) Patent Application Publication
(10) Pub. No.: US 2009/0289328 A1
(43) Pub. Date: Nov. 26, 2009

(54) INSULATION FILM FOR CAPACITOR ELEMENT, CAPACITOR ELEMENT AND SEMICONDUCTOR DEVICE

(75) Inventor: Masami Tanioku, Tokyo (JP)

Correspondence Address: YOUNG & THOMPSON, 209 Madison Street, Suite 500, ALEXANDRIA, VA, 22314, US

(73) Assignee: Elpida Memory, Inc., Tokyo (JP)

(21) Appl. No.: 12/470,873

(22) Filed: May 22, 2009

(30) Foreign Application Priority Data
May 22, 2008 (JP) 2008-134015

(51) Int. Cl. H01L 29/92; H01G 4/06; E04B 1/76

(52) U.S. Cl. 257/532; 361/321.5; 252/62; 257/E29.342

(57) ABSTRACT

An insulation film includes niobium, oxygen and a metal element, and the insulation film has a band gap width of larger than 4.2 eV, and at least a portion of the insulation film includes an amorphous structure.

### BACKGROUND OF THE INVENTION

1. Field of the Invention

The present invention relates to an insulation film for a capacitor element, a capacitor element, and a semiconductor device.

Priority is claimed on Japanese Patent Application No. 2008-134015, filed May 22, 2008, the content of which is incorporated herein by reference.

2. Description of Related Art

In conjunction with progress toward miniaturization and higher integration of DRAM, the size of the capacitor elements that configure memory cells has also contracted, thereby making it difficult to ensure a sufficient amount of stored charge. In order to ensure the amount of stored charge, development is progressing with respect to the application to capacitor elements of insulation film having high permittivity. As regards capacitor elements that configure DRAM memory cells, it is important not only to have high permittivity of the insulation film, but also to inhibit leakage current from the insulation film.

Among the variety of high-permittivity films for capacitor elements, niobium pentoxide (Nb₂O₅) film is one promising candidate. With respect to the relative permittivity of niobium pentoxide film, very large values are obtained on the order of 50 in an amorphous state, and on the order of 135 in a crystalline state. Thus, while niobium pentoxide enables easy formation of film having high permittivity, inhibition of leakage current is difficult, and application to DRAM capacitor elements is problematic.

In order to inhibit leakage current while putting to good use the high permittivity of niobium pentoxide, a method has been proposed which combines niobium pentoxide and another material to form the insulation film of the capacitor element (see, Japanese Unexamined Patent Application, First Publication No. 2002-164516 and Japanese Unexamined Patent Application, First Publication No. 2004-327607, which are hereinafter referred to as “Patent Documents 1 and 2, respectively). The insulation film disclosed in Patent Documents 1 and 2 is formed by crystallization of a combination of niobium pentoxide and tantalum pentoxide (Ta₂O₅).

However, although Patent Document 1 discloses the heat treatment temperatures for formation of the insulation film, and evaluations of the permittivity of the insulation film, it discloses nothing regarding leakage current values of the insulation film. The present inventors conducted an evaluation of leakage current values using completely crystallized insulation film identical to the insulation film disclosed in Patent Document 1. As a result, it was found with respect to use as a capacitor element in DRAM memory cells that leakage current is large, and that inhibition of leakage current is required.

Patent Document 2 discloses insulation film in which amorphous oxides exist in the crystal grain boundary areas of oxides in a crystalline state. However, it is extremely difficult to stably manufacture insulation film with this type of structure merely by temperature control. That is, it is difficult to have amorphous material exist uniformly at all crystal grain boundary areas, with the result that it is difficult to form insulation film having the property of a uniform leakage current value regardless of location.

### SUMMARY

In one embodiment, there is provided an insulation film that includes niobium, oxygen and a metal element, and the insulation film having a band gap width of larger than 4.2 eV, and at least a portion of the insulation film including an amorphous structure.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional schematic view that shows one example of a capacitor element according to a first embodiment of the present invention;

FIG. 2A is a cross-sectional schematic view that shows another example of a capacitor element having a columnar shape according to the first embodiment of the present invention;

FIG. 2B is a cross-sectional schematic view that shows yet another example of a capacitor element having a cylindrical shape according to the first embodiment of the present invention;

FIG. 3 is a planar schematic view showing a semiconductor device according to the first embodiment of the present invention;

FIG. 4 is a cross-sectional schematic view taken along a section line A-A′ in FIG. 3;

FIG. 5 is a cross-sectional, schematic view that shows a capacitor element for evaluation of examples;

FIG. 6 is a graph that shows the relation between the yttrium concentration (%) of the insulation film of example 1 and relative permittivity and leakage withstand voltage;

FIG. 7 is a graph that shows the relation between the tantalum concentration (%) of the insulation film of example 2 and relative permittivity and leakage withstand voltage; and

FIG. 8 is a graph that shows the relation between the tantalum addition ratio of the insulation film of example 2 and the band gap.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

FIG. 1 is a cross-sectional view showing a capacitor element that is formed using an insulation film according to a first embodiment of the present invention. The capacitor element shown in FIG. 1 is configured from an insulation film 3 that is interposed between a lower electrode 1 and an upper electrode 2 (pair of electrodes) composed of titanium nitride (TiN). Titanium nitride is used as the constituent material of the lower electrode 1 and upper electrode 2, but one is not particularly limited to this material. As constituent material of the lower electrode 1 and upper electrode 2, it is also possible to use polycrystalline silicon film or metallic film of platinum (Pt), ruthenium (Ru), iridium (Ir) and the like. It is also acceptable to form the lower electrode 1 and upper electrode 2 from different materials.

The band gap of niobium pentoxide (Nb₂O₅) film alone is 4.2 eV in terms of energy level. The insulation film 3 according to the present embodiment is formed by adding to niobium pentoxide a metal element which composes a metal oxide that has a large band gap and a high relative permittivity relative to niobium pentoxide. Therefore, the band gap of the insulation film 3 is larger than that of niobium pentoxide of 4.2 eV.

Specifically, the insulation film 3 is formed by adding one or more of the elements selected from among yttrium (Y), aluminum (Al), tantalum (Ta), and the lanthanoid elements—which are metal elements that compose metal oxides having a large band gap and high relative permittivity with respect to niobium pentoxide (NB₂O₅)—to niobium pentoxide Here, “lanthanoid elements” signify the elements from lanthanum (La) with an atomic number of 57 to lutetium (Lu) with an atomic number of 71. The band gap of yttrium oxide (Y₂O₃) is 6.0 eV. The band gap of aluminum oxide (Al₂O₃) is 8.0 eV. The band gap of tantalum oxide (Ta₂O₅) is 5.3 eV. The band gap of lanthanum oxide (La₂O₃) is 5.4 eV. Each of yttrium oxide, aluminum oxide, tantalum oxide, and lanthanum oxide has a larger band gap than that of niobium pentoxide of 4.2 eV. Among these, aluminum oxide has the largest band gap value. Namely, the band gaps of these metal oxides are in the range of larger than 4.2 eV and not larger than 8.0 eV. Therefore, the band gap of the insulation film 3 including niobium oxide and the above metal oxide is in the range of larger than 4.2 eV and less than 8.0 eV.

It is preferable that the insulation film 3 have at least partially an amorphous structure, and that it not be completely crystallized. The meaning of a “not completely crystallized” state extends to a state in which the entire structure is in a completely amorphous state, and the structure has a short-range order.

Even when the insulation film 3 according to the present embodiment is in a state that is not completely crystallized, it is possible to satisfy the required electrical properties of the capacitor element.

The permittivity and leakage current properties of the insulation film 3 vary according to the concentration of the aforementioned elements that are added to niobium pentoxide. That is, the relative permittivity of the insulation film 3 increases as the concentration of the aforementioned elements that are added to niobium pentoxide decreases, and the leakage withstand voltage of the insulation film 3 increases as the concentration of the aforementioned elements that are added increases.

In the present embodiment, as the metal elements that are added to niobium pentoxide, it is acceptable to have one or more selected from among yttrium, aluminum, tantalum, and the lanthanoid elements. There are no problems with respect to the properties of the insulation film 3 even if two or more of these metal elements are added to niobium pentoxide, but when considered in terms of mass productivity in the manufacturing process, it is preferable that only one of these be added.

The addition ratio of the metal element(s) to be added can be expressed by the concentration ratio relative to the entirety obtained by joining the niobium (Nb) and the added element(s). For example, in the case where yttrium (Y) is added to niobium pentoxide, the addition ratio of Y(Y/(Y+Nb)) is 10%-50%. In this way, an insulation film is obtained which balances both leakage withstand voltage and relative permittivity, supposing the case of application of a capacitor element as a DRAM memory cell.

In the case where tantalum (Ta) is added to niobium pentoxide, the addition ratio of Ta(Ta/(Ta+Nb)) is 40%-80%. In this way, an insulation film is obtained which balances both the leakage withstand voltage and relative permittivity of the capacitor element.

Even in cases where aluminum or a lathanoid element is used as the additive element, an appropriate amount of the element is added to niobium pentoxide so as to obtain the desired capacitor properties.

With respect to the insulation film 3 according to the present embodiment, even if a small amount of the respective element is added to niobium pentoxide, it is possible to obtain better properties as insulation film of a capacitor element than with insulation film composed only of niobium pentoxide. Accordingly, in the case where, for example, yttrium is selected as the additive element, its addition ratio is not limited to within 10%-50%, and it is also possible to add 10% or less, or 50% or more. The recommended concentrations of these additive elements also vary according to film thickness and film formation method.

The insulation film 3 according to the present embodiment can be formed by the sputtering method, normal CVD (chemical vapor deposition) method, ALD (atomic layer deposition), and so on using an ordinary semiconductor manufacturing apparatus.

The method for manufacturing the insulation film 3 by adding yttrium to niobium pentoxide using the sputtering method is described below.

In FIG. 1, after forming the lower electrode 1 with titanium nitride or the like, the Nb₂O₅ target and the Y₂O₃ target are disposed within a chamber of a sputtering apparatus. Next, while rotating the surface (the insulation-film-formation face) of the lower electrode 1 that is disposed at a position opposite the respective targets, electric discharge is caused by respectively supplying RF (high frequency) power to each target. By this means, insulation film which is composed of niobium pentoxide to which yttrium (Y) has been added is formed on top of the lower electrode 1.

In the case where an insulation film which is composed of niobium pentoxide to which yttrium has been added is formed according to the above method, the additive amount of yttrium in the niobium pentoxide is proportional to the amounts of the raw materials constituting the insulation film that are supplied to the surface of the lower electrode 1 from each target. That is, adjustment of the amounts of the raw materials constituting the insulation film that are supplied from the targets is conducted by a method for controlling RF power, enabling formation of niobium pentoxide films with different additive amounts of yttrium.

The amount of the raw materials constituting the insulation film that are supplied from the target to the lower electrode surface can also be varied by a method for changing the yttrium content that is contained in the target. Accordingly, it is also possible to change the additive amount of yttrium in the niobium pentoxide by changing the yttrium content that is contained in the target that is used when forming the insulation film.

It is also acceptable to control the additive amount by controlling the amounts of the raw materials constituting the insulation film that are supplied to the film formation face from the targets using a combination of the method for controlling the RF power that is supplied to the targets and the method for changing the yttrium content that is contained in the target.

It is also acceptable to similarly control the additive amount of yttrium using a target that is formed from material containing yttrium other than Y₂O₃.

In the foregoing example, a method was described for forming insulation film composed of niobium pentoxide to which yttrium is added In cases where insulation film is formed which is composed of niobium pentoxide to which elements other than yttrium are added, it is similarly possible to control the additive amount of the element in the niobium pentoxide by the method for changing the RF power that is supplied to the targets and/or the method for changing the content of the additive element contained in the target.

After forming the insulation film 3 on top of the lower electrode 1, annealing (heat treatment) is conducted for 1 minute to 10 minutes in an oxygen atmosphere at a temperature of 500° C.-700° C. The objective of this annealing is not to completely crystallize the insulation film 3, but to improve film quality. In the case where the insulation film 3 is formed by the sputtering method at around 300° C., it may happen that defects occur on the film, or that oxidation of the insulation film 3 is insufficient, and thereby the leakage properties of the insulation film 3 may be impaired. By conducting annealing after film formation, film defects originating in low temperature formation of the insulation film 3 can be ameliorated, and leakage properties can be further improved. The temperature and time of this annealing can be determined according to the film formation method of the insulation film 3 and the leakage properties that are required in the insulation film 3. With respect to the apparatus used for annealing, either a furnace apparatus or a lamp annealing apparatus is acceptable.

The occurrence of film defects can be inhibited during film formation of the insulation film 3 in the case where a sophisticated sputtering technology such as one that employs oxidants is used when forming the insulation film 3 by the sputtering method, or in the case where the insulation film 3 is formed by a film formation method such as the CVD method. Consequently, in such cases, one may dispense with conduct of an annealing process after film formation.

That is, with respect to the method of formation of the insulation film 3 according to this embodiment, post-film-formation annealing is not an indispensable process. Whether or not to conduct annealing may be determined according to the properties that are ultimately to be obtained by application to semiconductor devices such as DRAM. Even when annealing is conducted, it is possible to vary conditions such as temperature and time according to the desired properties of the insulation film 3.

Moreover, the insulation film 3 according to the present embodiment can obtain the desired capacitor properties even in a state where the film is not completely crystallized. Accordingly, when the insulation film 3 is used in an amorphous state, there is no occurrence of the problem of surface roughness that stems from crystallization.

In the case where the insulation film 3 is a completely crystallized film, as it is affected by the crystallinity of the material that composes the lower electrode 1 during crystallization, the quality of the insulation film 3 is highly dependent on the material and film quality of the lower electrode 1, resulting in major practical limitations and difficulties. On the other hand, as the insulation film 3 according to the present embodiment does not need to be completely crystallized, and as it may be used even in an amorphous state, it is possible to offer a fixed quality that is independent of the quality of the lower electrode 1. Consequently, formation of the lower electrode 1 and insulation film 3 is easy, and options pertaining to the material and method of formation of the lower electrode 1 can be increased.

Moreover, as there is no need to control the substance so as to be segregated at the crystal grain boundary of the niobium pentoxide, and as the element that is added to the niobium exists in a mixed state, it is possible to easily manufacture an insulation film with uniform properties regardless of location.

After conducting formation and, if necessary, annealing of the insulation film 3, the capacitor element is completed upon formation of the upper electrode 2.

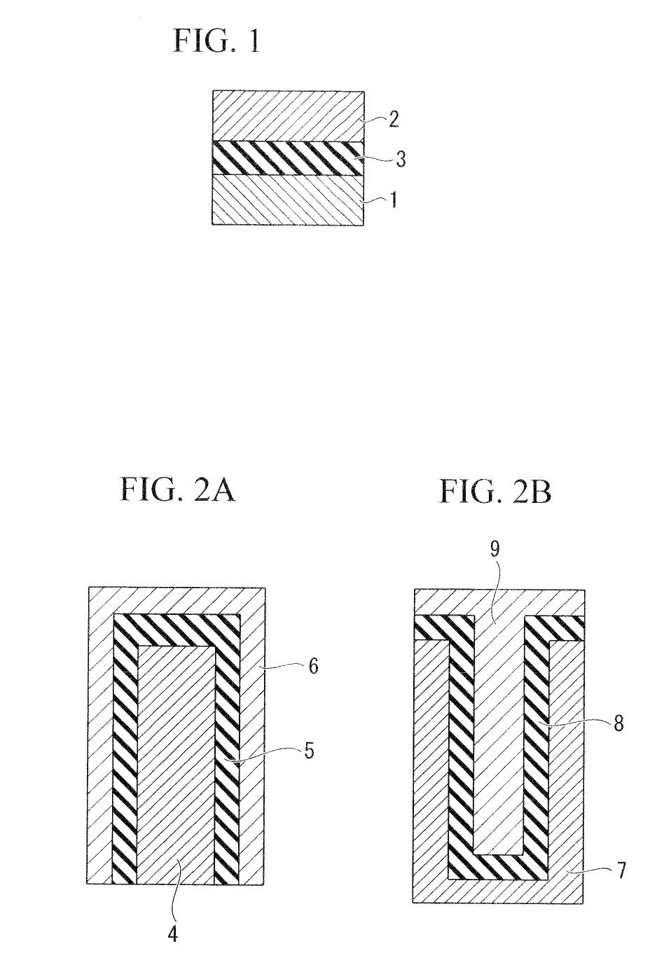

The capacitor element according to the present embodiment may be applied not only in planar form, but also when the electrodes have a three-dimensional structure. A description is given of a capacitor element having a three-dimensional structure with reference to FIG. 2A and FIG. 2B.

FIG. 2A is a vertical cross-sectional view showing a capacitor element having a columnar shape (pillar shape). The capacitor element shown in FIG. 2A includes a lower electrode 4, insulation film 5, and upper electrode 6. The lower electrode 4 is formed in a columnar shape using a high-melting-point metal such as titanium nitride. The insulation film 5 is an insulation film for a capacitor element which is formed by one of the previously described methods so as to cover the upper face and side faces of the lower electrode 4. The upper electrode 6 is formed so as to cover the insulation film 5 using a high-melting-point metal such as titanium nitride. As the material of these electrodes, one may use material other than titanium nitride.

FIG. 2B is vertical cross-sectional view showing a capacitor element having a cylindrical shape. The capacitor element shown in FIG. 2B includes a lower electrode 7, insulation film 8, and upper electrode 9. The lower electrode 7 uses a high-melting-point metal such as titanium nitride to form a hollow cylindrical shape. The insulation film 8 is insulation film for a capacitor element that is formed by one of the previously described methods so as to cover the inner wall and top face portions of the lower electrode 7. The upper electrode 9 is formed so as to cover the insulation film 8 using high-melting-point metal such as titanium nitride.

As shown in FIG. 2A or FIG. 2B, by giving the upper electrode and lower electrode a three-dimensional structure, it is possible to form a capacitor element of large capacity in the same occupied area.

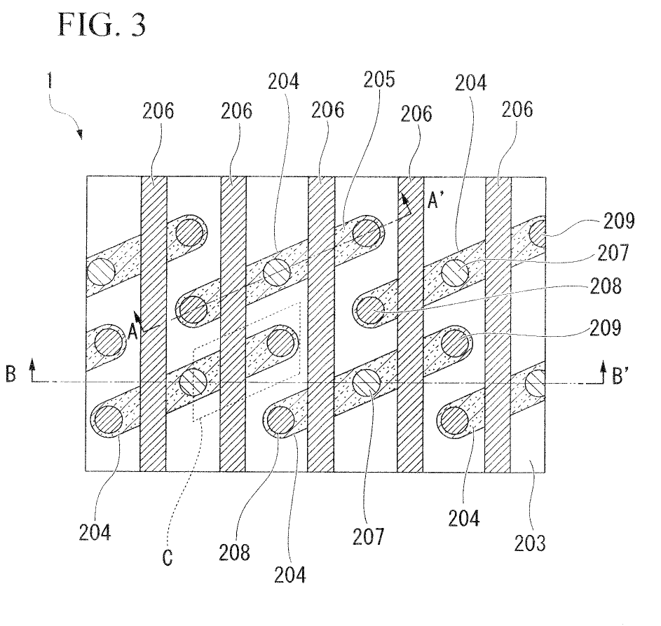

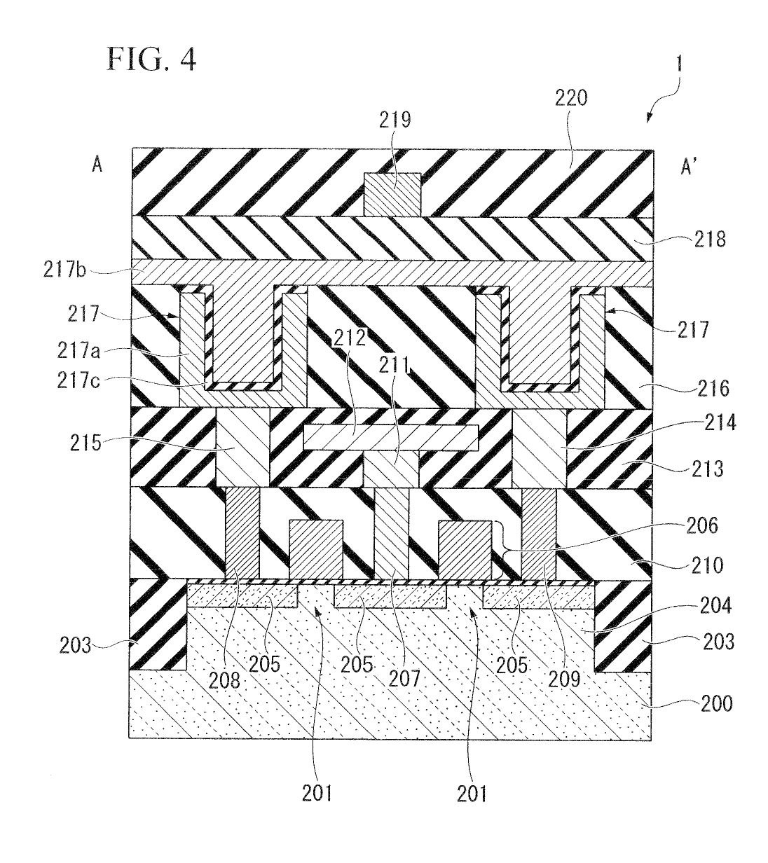

Below, as a specific example of a semiconductor device using the capacitor element according to the present embodiment, the case of application to a DRAM memory cell is described FIG. 3 shows a planar view of a part of a DRAM memory cell.

As shown in FIG. 3, a plurality of active regions (diffusion layer regions) 204 are disposed on a semiconductor substrate (not illustrated in the figure). The active regions 204 are divided by element isolation regions 203. Using means that are public knowledge, the element isolation regions 203 are formed by embedding insulation film such as silicon oxide film in the semiconductor substrate.

A plurality of gate electrodes 206 are disposed on the semiconductor substrate so as to cross the active regions 204. The gate electrodes 206 function as DRAM word lines. In the portion of the active region 204 that is not covered with the gate electrode 206, an impurity such as phosphorus is ion injected to form an N-type diffusion layer region. This N-type diffusion layer region functions as the source drain region of a transistor.

In FIG. 3, the portion that is surrounded with a broken line C forms a single MOS-type transistor.

At the center of each active region 204, a contact plug 207 is provided, and contacts the N-type diffusion layer region on the surface of the active region 204. Contact plugs 208 and 209 are provided at both ends of each active region 204, and these contact the N-type diffusion layer region on the surface of the active region 204. The contact plugs 207, 208 and 209 can be simultaneously formed.

In the layout shown in FIG. 3, in order to arrange the memory cell with high density, an arrangement is made in which two neighboring transistors share one contact plug 207. In a subsequent process, a plurality of wiring layers (not illustrated in the figure) are formed that run in the direction along a line B-B′, that contact the contact plug 207, and that cross the gate electrode 206. These wiring layers function as DRAM bit lines. The contact plugs 208 and 209 are respectively connected to the capacitor element (not illustrated in the figure) according to the present embodiment.

FIG. 4 shows a cross-sectional view showing the DRAM memory cell taken along a section line A-A′ in FIG. 3. FIG. 4 shows a semiconductor substrate 200 that is composed of P-type silicon, MOS-type transistors 201, and gate electrodes 206 that function as word lines. N-type diffusion layer regions 205 are formed on portions of the surface of the active region 204, and contact the contact plugs 207, 208, and 209. As the material of the contact plugs 207, 208 and 209, it is possible to use polycrystalline silicon into which phosphorus is introduced. In FIG. 4, an interlayer insulation film 210 is shown that is provided on top of the transistors. The contact plug 207 is connected to a wiring layer 212 that functions as a bit line via a contact plug 211. As the material of the wiring layer 212, tungsten may be used. The contact plugs 208 and 209 are respectively connected to a capacitor element 217 according to the present embodiment via contact plugs 214 and 215.

The capacitor element 217 is composed of a lower electrode 217a, upper electrode 217b, and insulation film 217c that is interposed between the lower electrode 217a and the upper electrode 217b. The insulation film 217c is composed of the same material as the insulation films 3, 5, and 8 that were described above. The capacitor element 217 shown in FIG. 4 is cylindrically shaped in the same manner as the capacitor element shown in FIG. 2B, but it is also possible to used capacitor elements of other shapes.

Furthermore, FIG. 4 shows interlayer insulation films 213, 216, and 218 that serve to provide insulation between the respective wirings, a wiring layer 219 that is formed using aluminum or the like and that is positioned on the top layer, and a surface protection film 220.

By turning on the MOS-type transistor 201, it is possible to determine whether or not electric charge has accumulated in the capacitor element 217 via the bit line (wiring layer 212), and to conduct operations as a DRAM memory cell that is capable of conducting information storage operations.

With respect to the capacitor element according to the present embodiment, not only is the permittivity of the insulation film high, but leakage current can also be inhibited, thereby enabling easy formation of memory cells that have excellent charge retention properties (refresh properties) Accordingly, it is possible to easily manufacture high-performance DRAM.

The capacitor element according to the present embodiment can also be used apart from DRAM memory cells and may also be applied, for example, to common semiconductor devices such as logic that do not have memory cells, so long as it is a device that uses a capacitor element.

An insulation film for a capacitor element and a capacitor element according to an embodiment of the present invention enable coexistence of high permittivity and lea age current inhibition, and have an excellent uniformity of properties. Moreover, a semiconductor device according to an embodiment of the present invention has excellent charge retention properties (refresh properties).

### EXAMPLE 1

As example 1, an evaluation of the properties of a capacitor element which uses insulation film that is formed by adding yttrium to niobium pentoxide film is stated below.

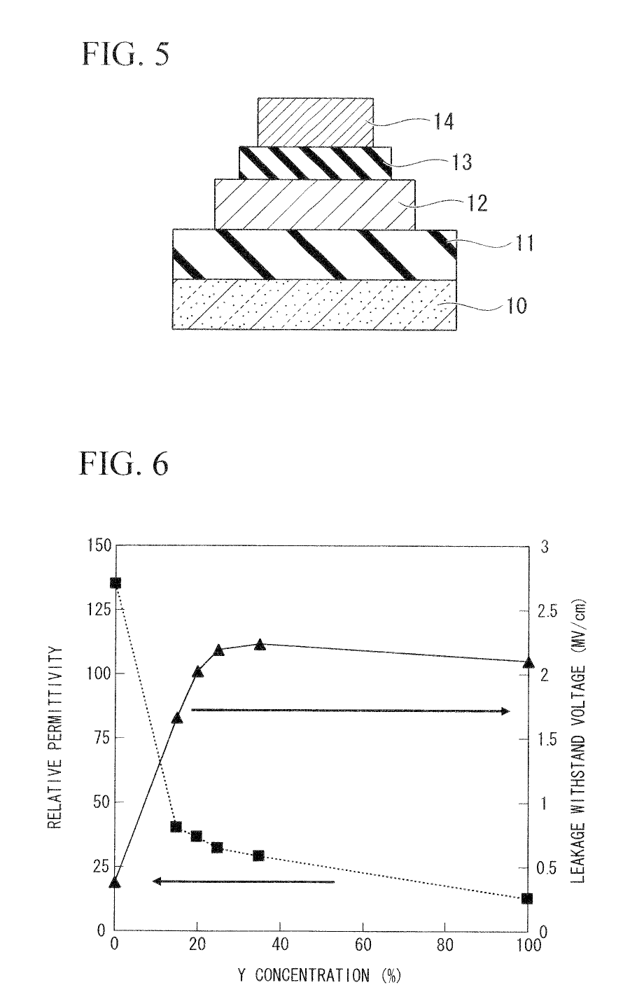

First, the method of manufacture of the capacitor element used for evaluation is described As shown in FIG. 5, a silicon oxide film 11 (SiO₂) was formed to a thickness of 50 nm by 1000° C. wet oxidation on top of a silicon substrate 10. Next, as a lower electrode, a platinum (Pt) film 12 was formed to a film thickness of 100 nm by the sputter method with DC discharge at 50 W power, at pressure of 1.0 Pa in an argon (Ar) gas atmosphere, and with the substrate temperature at room temperature.

Next, as insulation film 13, niobium pentoxide film was formed with addition of yttrium using a multi-source sputtering apparatus. During fabrication, RF discharges were simultaneously conducted inside the chamber of the sputtering apparatus using targets of Nb₂O₅ and Y₂O₃. Here, the semiconductor substrate 10 on which the platinum film 12 (lower electrode) is deposited was disposed at the center of a position that is opposite the targets, and was rotated to form a uniform film thickness. The substrate temperature was set at 300° C., argon and oxygen (O₂) gases were simultaneously supplied at the same flow rate (10 sccm), and pressure inside the chamber was set to 0.5 Pa.

As the adhesion amounts on the platinum film 12 that serves as the lower electrode from the Nb₂O₅ and Y₂O₃ targets is proportionate to the RF power values that are given to the respective targets, the compositional ratio of niobium and yttrium is obtained by appropriately setting the respective RF power. The film thickness of the insulation film 13 was formed to 40 nm.

Next, a platinum film 14 that serves as an upper electrode was formed to approximately 30 nm under the same conditions as the platinum film 12 of the lower electrode, and the insulation film 13 was subjected to annealing treatment for 10 minutes at 600° C. by a furnace apparatus using oxygen gas, thereby forming the capacitor element.

FIG. 6 shows the measurement results of relative permittivity and leakage withstand voltage when the addition ratio of yttrium relative to niobium (Y/(Y+Nb)) was varied in a range of 0-100% with respect to the niobium pentoxide film. Leakage withstand voltage is shown by the intensity (MV/cm) of the electric field that is applied when current flow occurs at a value of 10 nA per unit area (1 cm²).

From FIG. 6, it is clear that addition of yttrium lowers relative permittivity, but greatly enhances leakage withstand voltage. Even when yttrium is added in small amounts, the effect of enhanced leakage withstand voltage is evident As the tendency of improvement in leakage withstand voltage is no longer evident when the yttrium ratio exceeds 50%, it is preferable that the yttrium addition amount be set at 50% or less.

### EXAMPLE 2

As example 2, evaluation of the properties of a capacitor element which uses an insulation film that is formed by the addition of tantalum (Ta) to niobium pentoxide film is stated below.

With the exception of the insulation film, the capacitor element was formed by the same method as example 1, and platinum film was used as the lower electrode of the capacitor element. The insulation film was formed by the sputtering method, and Nb₂O₅ and Ta₂O₅ were used as the targets during film formation. The insulation film was subjected to annealing treatment for 10 minutes at 600° C. by a furnace apparatus using oxygen gas. After this annealing, the insulation film was in a state that was not completely crystallized. By controlling the RF power supplied to the respective targets, the addition ratio of tantalum relative to niobium (Ta/(Ta+Nb)) was varied in a range of 0-100%.

Table 1 shows the results of measurement of the ratio of tantalum and niobium in the formed insulation film measured by the RBS (Rutherford Backscattering Spectrometry) method.

TABLE 1

| | |
|---|---|
| RF power (W) | Ta/(Ta + Nb) |

| Ta₂O₅ | Nb₂O₅ | (%) |
|---|---|---|
| 0 | 50 | 0 |
| 14 | 50 | 18.4 |
| 22 | 50 | 32.2 |
| 41 | 50 | 51.4 |
| 50 | 20 | 80.7 |
| 50 | 0 | 100 |

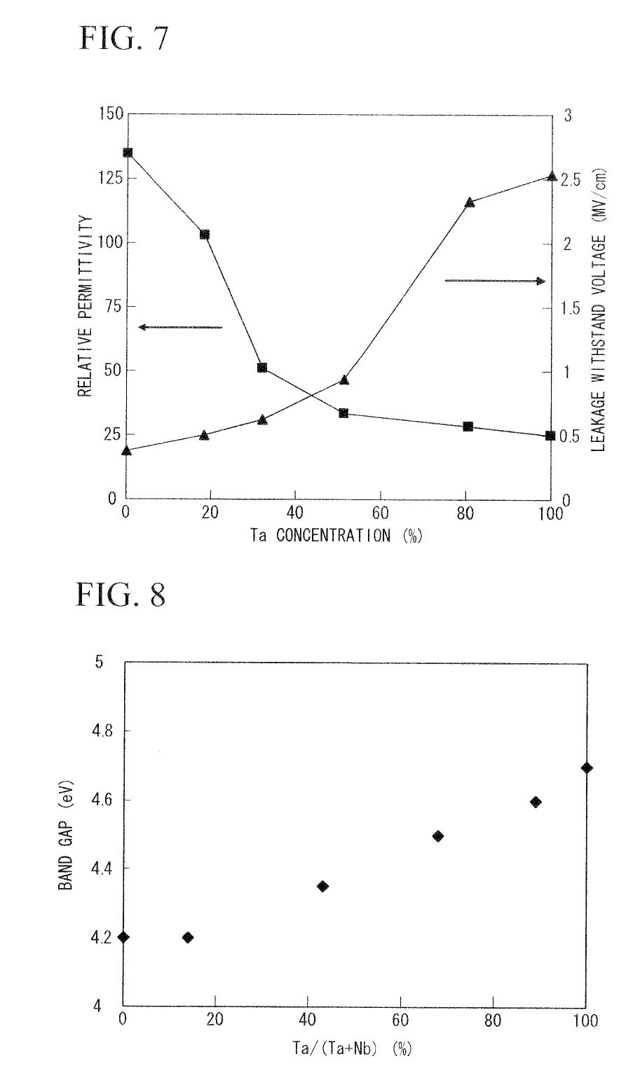

FIG. 7 shows the measurement results of relative permittivity and leakage withstand voltage of the formed capacitor element. As in FIG. 6, leakage withstand voltage is shown by the intensity (MV/cm) of the electric field that is applied when current flow occurs at a value of 10 nA per unit area (1 cm²). As shown in FIG. 7, it is clear that although the addition of tantalum decreases relative permittivity, it greatly enhances leakage withstand voltage.

FIG. 8 shows the results of spectral analysis by the XPS (X-ray photoelectron spectroscopy) method of insulation films that have different ratios of tantalum and niobium, with extraction of the energy loss portion of the band gap that is contained in the spectrum. The horizontal axis is the ratio of tantalum and niobium, and the vertical axis is the band gap value.

From FIG. 8, it is clear that band gap values continuously change from Nb₂O₅ film (the case of a 0% tantalum ratio) to Ta₂O₅ film (the case of a 100% tantalum ratio), and that leakage withstand voltage (FIG. 7) changes in accordance therewith. Moreover, with respect to the insulation film of the present embodiment, tantalum is not segregated at the crystal grain boundaries of niobium pentoxide, which suggests that the insulation film is formed from a single material in which niobium and tantalum are mixed.

It is apparent that the present invention is not limited to the above embodiments, but may be modified and changed without departing from the scope and spirit of the invention.

What is claimed is:

1. An insulation film comprising niobium, oxygen and a metal element, and at least a portion of the insulation film including an amorphous structure.

2. The insulation film according to claim 1, wherein the insulation film comprises an oxide of the metal element, and a band gap of the oxide is larger than the band gap of niobium pentoxide.

3. The insulation film according to claim 1, wherein the insulation film has the band gap width of larger than 4.2 eV.

4. The insulation film according to claim 1, wherein the metal element comprises at least one element selected from among yttrium, aluminum, tantalum, and lanthanoids.

5. The insulation film according to claim 1, wherein the metal element comprises yttrium, and a ratio of yttrium relative to a total of yttrium and niobium in the insulation film is at most 50%.

6. A capacitor element comprising a pair of electrodes and an insulation film interposed between the pair of electrodes,
wherein the insulation film comprises niobium, oxygen and a metal element, and at least a portion of the insulation film includes an amorphous structure.

7. The capacitor element according to claim 6, wherein the insulation film comprises an oxide of the metal element, and a band gap of the oxide is larger than the band gap of niobium pentoxide.

8. The capacitor element according to claim 6, wherein the insulation film has a band gap width of larger than 4.2 eV.

9. The capacitor element according to claim 6, wherein the metal element comprises at least one element selected from among yttrium, aluminum, tantalum, and lanthanoids.

10. The capacitor element according to claim 6, wherein the metal element comprises yttrium, and a ratio of yttrium relative to a total of yttrium and niobium in the insulation film is at most 50%.

11. A semiconductor device comprising a capacitor element including a pair of electrodes and insulation film interposed between the pair of electrodes,
wherein the insulation film comprises niobium, oxygen and a metal element and at least a portion of the insulation film includes an amorphous structure.

12. The semiconductor device according to claim 11, wherein the insulation film comprises an oxide of the metal element, and a band gap of the oxide is larger than the band gap of niobium pentoxide.

13. The semiconductor device according to claim 11, wherein the insulation film has a band gap width of larger than 4.2 eV.

14. The semiconductor device according to claim 11, wherein the metal element comprises at least one element selected from among yttrium, aluminum, tantalum, and lanthanoids.

15. The semiconductor device according to claim 1, wherein the metal element comprises yttrium, and a ratio of yttrium relative to a total of yttrium and niobium in the insulation film is at most 50%.

16. The semiconductor device according to claim 13, further comprising a memory cell including the capacitor element and a transistor,
wherein operation of data storing is conducted by determining whether or not electric charge is accumulated in the capacitor element.

17. The semiconductor device according to claim 16, wherein the metal element comprises at least one element selected from among yttrium, aluminum, tantalum, and lanthanoids.

18. The semiconductor device according to claim 16, wherein the metal element comprises yttrium, and a ratio of yttrium relative to a total of yttrium and niobium in the insulation film is at most 50%.
